(19) United States
(12) Patent Application Publication
(10) Pub. No.: US 2026/0354100 A1
(43) Pub. Date: Nov. 5, 2026

(54) HOLDING DEVICE

(71) Applicant: Niterra Co., Ltd., Nagoya-shi, Aichi (JP)

(72) Inventors: Akira INAYOSHI, Nagoya-shi (JP); Atsushi SUZUKI, Nagoya-shi (JP)

(21) Appl. No.: 19/161,398

(22) PCT Filed: Apr. 3, 2024
(86) PCT No.: PCT/JP2024/013756

§ 371 Date: Sep. 2, 2025

(30) Foreign Application Priority Data
Apr. 18, 2023 (JP) 2023-067630

(51) Int. Cl. H10P 72/72; H10P 72/76

(52) U.S. Cl. CPC H10P 72/722; H10P 72/7616

(57) ABSTRACT

A holding device includes: a plate-shaped portion formed in a plate shape; a base portion supporting the plate-shaped portion and formed in a plate shape; and an adhesive layer disposed between the plate-shaped portion and the base portion and including an adhesive and an inorganic filler, the adhesive layer joining the plate-shaped portion and the base portion. The inorganic filler includes an aluminum nitride particle in which a second phase containing yttrium is present.

### TECHNICAL FIELD

The present disclosure relates to a holding device.

### BACKGROUND ART

As holding devices for holding target objects, for example, electrostatic chucks for holding target objects such as wafers at the time of manufacturing semiconductors have been known. In general, each of the electrostatic chucks includes: a plate-shaped portion on which a target object is placed; a base portion supporting the plate-shaped portion; and an adhesive layer joining the plate-shaped portion and the base portion. In a case where the amount of heat entering the plate-shaped portion increases as in a case where the electrostatic chuck is used while being exposed to plasma with a higher output, the adhesive layer is required to have a high thermal conductivity in order to dissipate the heat to the base portion.

Conventionally, aluminum nitride sintered granules are used as a heat-dissipation-material filler for filling an adhesive or the like so as to improve heat dissipation properties. For example, Patent Document 1 describes aluminum nitride (AlN) sintered granules having, while the sphericities thereof are maintained, shapes with projections formed on the surfaces of the AlN sintered granules so that high thermal conduction properties can be imparted to a resin composition obtained by filling a resin therewith.

### PRIOR ART DOCUMENT

### Patent Document

Patent Document 1: Japanese Patent Application Laid-Open (kokai) No. 2022-147702

Patent Document 2: Japanese Patent No. 6886439

### SUMMARY OF THE INVENTION

### Problem to be Solved by the Invention

However, even an adhesive layer obtained by using the aluminum nitride (AlN) described in Patent Document 1 as a filler has a problem in that a sufficient thermal conductivity is not obtained. These problems are not only present in such electrostatic chucks but also commonly present in various holding devices exemplified by semiconductor manufacturing devices such as etching devices in which plasma is utilized.

The present disclosure has been made to solve at least one of the above problems, and an object of the present disclosure is to provide a technology for improving thermal conduction through an adhesive layer in a holding device for holding a target object.

### Means for Solving the Problem

The present disclosure can be implemented as the following aspects.
(1) One aspect of the present disclosure provides a holding device configured to hold a target object. The holding device includes: a plate-shaped portion formed in a plate shape; a base portion supporting the plate-shaped portion and formed in a plate shape; and an adhesive layer disposed between the plate-shaped portion and the base portion and including an adhesive and an inorganic filler, the adhesive layer joining the plate-shaped portion and the base portion. The inorganic filler includes an aluminum nitride particle in which a second phase containing yttrium is present.

In the holding device in this aspect, the inorganic filler included in the adhesive layer includes an aluminum nitride particle in which a second phase containing yttrium is present. Since the second phase containing yttrium is deposited on at least one of the inside and the surface of the aluminum nitride particle, the amount of oxygen impurities in the aluminum nitride is decreased, whereby the thermal conductivity of the aluminum nitride particle as a filler can be improved. In addition, lattice defects in the aluminum nitride are decreased, and the reactivity with water can be decreased, whereby the surface of the aluminum nitride can be inhibited from turning into alumina (Al₂O₃) as a result of a reaction with water. Thus, the thermal conductivity of the aluminum nitride particle as a filler can be improved. As a result, thermal conduction through the adhesive layer can be improved.
(2) In the holding device of the above aspect, the aluminum nitride particle may have a surface on which phosphorus is present. With such a configuration, the wettability of each of the adhesive and the aluminum nitride particle is improved, and the transmission efficiency for lattice vibration is increased, whereby the thermal conductivity of the adhesive layer can be improved.
(3) In the holding device of the above aspect, the adhesive layer may have a glass transition temperature of 100 °C or lower. Such a configuration can cause the adhesive layer to, even at −100 °C, be flexible and have stress relaxation properties, whereby stable joining and thermal conduction with no in-plane variation can be realized.
(4) In the holding device of the above aspect, the adhesive layer may have: an elongation rate, at −60 °C, of 40% or higher; a shear strain, at −60 °C, of 100% or higher; and a storage elastic modulus, at −60 °C, of 30 MPa or lower. With such a configuration, when the holding device is used at a low temperature of about −60 °C, the adhesive layer can be inhibited from peeling from the plate-shaped portion or the base portion, the adhesive layer itself can be inhibited from being broken, and the plate-shaped portion can be inhibited from warping. Consequently, the controllability of a temperature distribution of a target object can be improved, and furthermore, the flatness of the plate-shaped portion can be inhibited from decreasing.

The present disclosure can be implemented in various aspects other than the above aspect and can be implemented in, for example, aspects such as a semiconductor manufacturing device including the holding device, a method for manufacturing the holding device, and a method for forming a joining portion.

### BRIEF DESCRIPTION OF THE DRAWINGS

FIG. 1 Diagram for schematically explaining a configuration of an electrostatic chuck.

FIG. 2 Diagram for schematically explaining a cross-sectional configuration of the electrostatic chuck.

FIG. 3 Diagram showing an SEM image of an adhesive layer.

FIG. 4 Diagram showing compositions, and evaluation results such as thermal conductivities and elongations, of respective samples.

FIG. 5 Diagram showing compositions, and evaluation results such as thermal conductivities and elongations, of respective samples.

FIG. 6 Diagram showing an advantageous effect exhibited by performing phosphoric acid treatment on aluminum nitride particles.

FIG. 7 Diagram showing a storage elastic modulus of an adhesive composition.

FIG. 8 Diagram for schematically explaining a method for calculating a shear strain.

### MODES FOR CARRYING OUT THE INVENTION

### A. Embodiment

### (A-1) Overall Configuration of Electrostatic Chuck

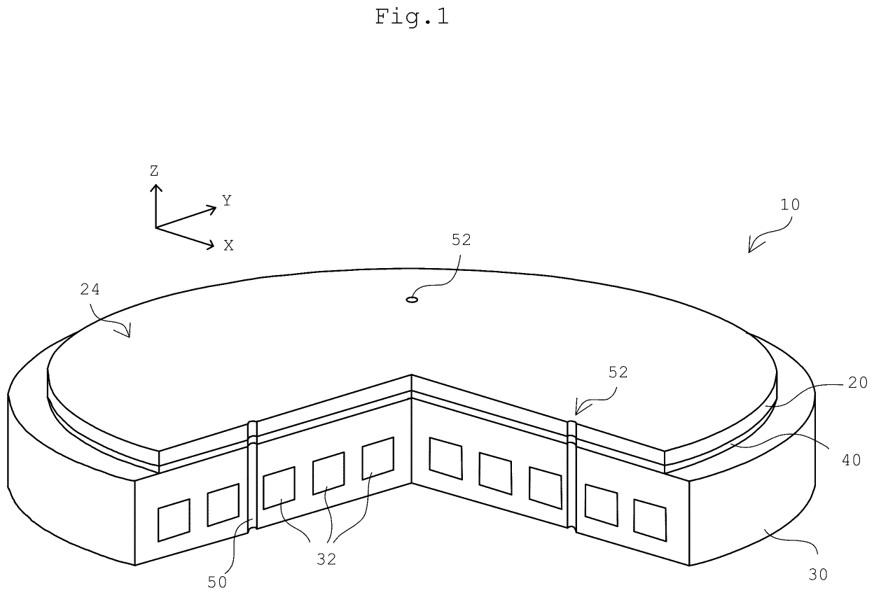

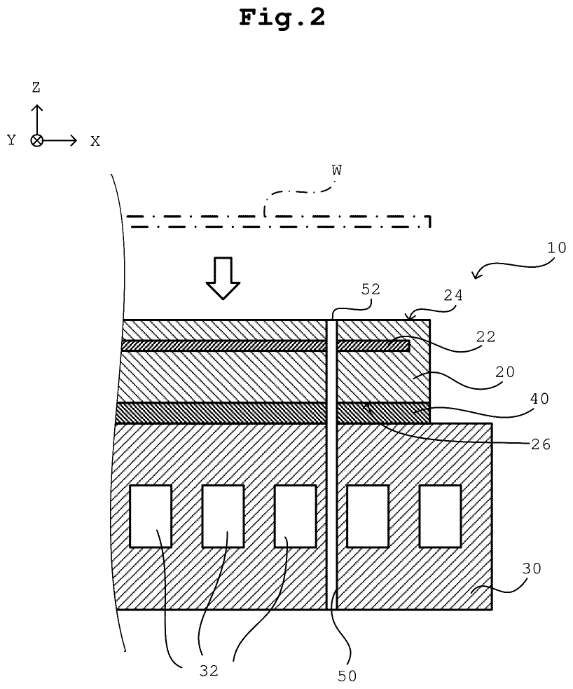

FIG. 1 is a diagram for schematically explaining a configuration of an electrostatic chuck 10 according to an embodiment. FIG. 2 is a diagram for schematically explaining a cross-sectional configuration of the electrostatic chuck 10. The electrostatic chuck 10 shown in FIG. 1 is partially cut. In addition, these drawings show X, Y, and Z axes orthogonal to one another in order to identify a direction. In the present description, the positive direction and the negative direction of the Z axis are respectively referred to as an upward direction and a downward direction for the sake of convenience. In actuality, however, the electrostatic chuck 10 may be installed such that directions thereof differ from such directions. The directions indicated by the X axis, the Y axis, and the Z axis are the same among the drawings. It is noted that the above drawings schematically show arrangement of constituents and do not accurately render the ratio among the dimensions of the respective constituents.

The electrostatic chuck 10 is a device for attracting and holding a target object by electrostatic attraction and is used for, for example, fixing a wafer W (FIG. 2) as a target object in a vacuum chamber of a semiconductor manufacturing device. The electrostatic chuck 10 includes a plate-shaped portion 20, a base portion 30, and an adhesive layer 40. These constituents are stacked in the order of the plate-shaped portion 20, the adhesive layer 40, and the base portion 30 in the-Z axial direction (vertically downward direction). The electrostatic chuck 10 according to the present embodiment is also referred to as “holding device”.

The plate-shaped portion 20 is a substantially circular plate-shaped member having: a first surface 24 on which the target object is to be placed; and a second surface 26 which is the reverse surface opposite to the first surface 24. The plate-shaped portion 20 is formed by containing, as a main component, ceramic (e.g., aluminum oxide, aluminum nitride, or the like). In the description of the present disclosure, a specific component being a “main component” or a “main constituent material” means that the content of the specific component is 50% by volume or higher. In another embodiment, the plate-shaped portion 20 may be formed by containing, as a main component, a material other than ceramic. The material is exemplified by a resin such as a polyimide, for example.

As shown in FIG. 2, an attraction electrode 22 is disposed inside the plate-shaped portion 20. The attraction electrode 22 is formed from, for example, an electrically conductive material such as tungsten or molybdenum. When voltage is applied from a power supply (not shown) to the attraction electrode 22, electrostatic attraction is generated. Owing to the electrostatic attraction, the wafer W is attracted and fixed to the first surface 24 of the plate-shaped portion 20. The attraction electrode 22 may be of a bipolar type or a unipolar type. In addition, a heater electrode (not shown) may be provided inside the plate-shaped portion 20. The heater electrode is configured as a resistance heating element formed from an electrically conductive material (e.g., tungsten, molybdenum, or the like) and is for heating the wafer W attracted and fixed to the first surface 24.

The base portion 30 is a plate-shaped member. The plate-shaped member is disposed on the second surface 26 side of the plate-shaped portion 20, supports the plate-shaped portion 20, has a cooling function, and is formed in a substantially circular shape. The base portion 30 may contain, for example, at least one type of metal among aluminum, magnesium, molybdenum, titanium, tungsten, and nickel. Among the above metals, molybdenum, titanium, and tungsten have comparatively small coefficients of thermal expansion. Therefore, formation of the base portion 30 by using at least one type of metal among molybdenum, titanium, and tungsten makes it possible to decrease the difference in coefficient of thermal expansion between the base portion 30 and the plate-shaped portion 20, and thus is desirable. In the description of the present disclosure, the “coefficient of thermal expansion” refers to a “coefficient of linear expansion”. Also, magnesium has a comparatively low Young's modulus. Therefore, formation of the base portion 30 by using magnesium makes it possible to decrease thermal stress to be generated in the base portion 30, and thus is desirable. Also, aluminum has a comparatively high thermal conductivity, is easily machined, and requires low cost. Therefore, formation of the base portion 30 by using aluminum makes it possible to increase the cooling efficiency, for the plate-shaped portion 20 and the wafer W, of the base portion 30 and to decrease manufacturing cost for the electrostatic chuck 10, and thus is desirable. From the viewpoint of decreasing the manufacturing cost while increasing the cooling efficiency of the base portion 30, the proportion of the metal contained in the base portion 30 is desirably high, and the base portion 30 desirably contains the metal as a main component. For example, the base portion 30 desirably contains 90% by mass or higher of highly versatile aluminum (e.g., is desirably formed from an aluminum alloy such as A6061 or A5052). However, the base portion 30 may contain a component other than metal, such as ceramic.

Inside the base portion 30, a plurality of coolant flow paths 32 are formed along an X-Y plane. Through the coolant flow paths 32, for example, a coolant such as a fluorine-based inert liquid, water, or liquid nitrogen is caused to flow so as to cool the base portion 30. Then, the plate-shaped portion 20 is cooled by heat transmission between the base portion 30 and the plate-shaped portion 20 via the adhesive layer 40, and thus the wafer W held on the first surface 24 of the plate-shaped portion 20 is cooled. Consequently, control of the temperature of the wafer W is realized. Instead of the embodiment in which the base portion 30 has therein the coolant flow paths 32, the base portion 30 may be configured to have a cooling function by cooling the base portion 30 from outside of the base portion 30. Alternatively, the base portion 30 does not have to have any cooling function. In a case where the base portion 30 does not have any cooling function, the electrostatic chuck 10 may be configured to cool the plate-shaped portion 20 from outside.

The adhesive layer 40 is disposed between the plate-shaped portion 20 and the base portion 30 and joins the plate-shaped portion 20 and the base portion 30. The adhesive layer 40 includes an adhesive formed from a resin material and an inorganic filler. The inorganic filler mainly includes aluminum nitride particles in which second phases containing yttrium are present. The adhesive layer 40 may further include various fillers (inorganic fillers) for adjusting properties of the adhesive layer 40 or properties of a paste for forming the adhesive layer 40. The adhesive layer 40 will be described later in detail.

In the electrostatic chuck 10, a plurality of gas supply paths 50 are further formed. Each of the gas supply paths 50 is provided so as to penetrate the plate-shaped portion 20, the adhesive layer 40, and the base portion 30 in the Z direction and leads to a gas discharge port 52 formed in the first surface 24 (see FIG. 1). Through the gas supply path 50, for example, an inert gas such as helium gas is supplied from a gas supply device (not shown) so that the inert gas is supplied from the gas discharge port 52 to the space between the first surface 24 and the wafer W. Consequently, the heat transmission properties between the plate-shaped portion 20 and the wafer W are increased, and the controllability of a temperature distribution of the wafer W is further increased. The gas supply path 50 may be dispensed with, i.e., the gas supply path 50 does not have to be provided to the electrostatic chuck 10.

### (A-2) Configuration of Adhesive Layer

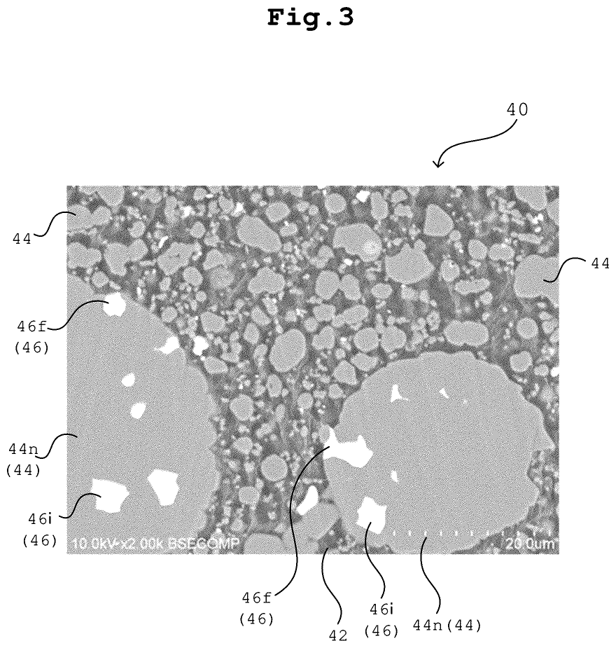

FIG. 3 is a diagram showing a scanning electron microscope (SEM) image of the adhesive layer 40. As shown in this drawing, the adhesive layer 40 includes an adhesive 42 and an inorganic filler 44. In FIG. 3, only some of a plurality of the inorganic fillers 44 are denoted by a reference character. The inorganic fillers 44 include aluminum nitride particles 44n in which second phases 46 containing yttrium are present. Here, a first phase is a main component, and the second phases mean partially deposited portions. The second phases 46 present in the aluminum nitride particles 44n are, for example, Y₃Al₅O₁₂ (YAG), Y₄Al₂O₉ (YAM), YAlO₃ (YAP), Y₂O₃, or the like. When oxygen impurities are solid-solved in aluminum nitride (AlN), the thermal conductivity is decreased. Meanwhile, the second phases represented by Al—Y—O are deposited in the aluminum nitride (AlN) in the aluminum nitride particles 44n of the present embodiment. Consequently, aluminum nitride having few oxygen impurities is formed, whereby the thermal conductivity of the filler (inorganic filler) can be improved. In addition, since the second phases represented by Al—Y—O are deposited in the aluminum nitride (AlN) in the aluminum nitride particles 44n, lattice defects in the aluminum nitride are decreased, and the reactivity with water is decreased, whereby the surface of the aluminum nitride can be prevented from turning into alumina as a result of a reaction with water. Thus, the thermal conductivity of the filler is increased.

The ratio between the aluminum nitride (AlN) and the yttrium (Y) of each of the aluminum nitride particles 44n is not particularly limited, and, for example, the ratio of Y to AlN is 0.5 to 2 with the amount of AlN being defined as 10. When the ratio of the yttrium (Y) is excessively low, the extent of decrease in lattice defects in the aluminum nitride (AlN) and the extent of decrease in oxygen impurities in the aluminum nitride (AlN) might become small, and the thermal conductivity of the AlN layer might not become sufficiently high. Meanwhile, when the ratio of the yttrium (Y) is excessively high, the amounts of YAM (2Y₂O₃·Al₂O₃), YAP (Y₂O₃·Al₂O₃), YAG (3Y₂O₃·5Al₂O₃), and Y₂O₃ in the particle are increased. These substances have lower thermal conductivities than AlN, and thus the thermal conductivity of the entirety of the particle is decreased. In a case where the amount of Y is moderate as in a case where the ratio of Y to AlN is 0.5 to 2 with the amount of AlN being defined as 10, heat is conducted through the AlN portion having a high thermal conductivity, whereby the thermal conductivity of the entirety of the particle can be increased.

As shown in the drawing, the second phases 46 are present on the insides and the surfaces of the aluminum nitride particles 44n included in the adhesive layer 40. In the following description, a second phase 46 present on the inside is also referred to as “on-inside second phase 46i”, and a second phase 46 present on the surface is also referred to as “on-surface second phase 46f”. The second phases 46 are preferably present on both the surfaces and the insides of the aluminum nitride particles 44n. In other words, both the on-inside second phase 46i and the on-surface second phase 46f are preferably present in each of the aluminum nitride particles 44n. Also, it is more preferable that the second phases 46 are finely dispersed than in a case where the second phases 46 are present in a concentrated manner at one location. The increase in the thermal conductivity of the aluminum nitride particles is considered to have resulted from efficient elimination of lattice defects and oxygen impurities in the aluminum nitride particles. In a case where portions of the yttrium (Y) are present only locally, it is considered that, at locations between distant ones of the portions, lattice defects and oxygen impurities remain and the thermal conductivity is low. Thus, it is preferable that the yttrium (Y) is finely dispersed. With the adhesive layer 40 being observed by using a scanning electron microscope (SEM), the existence location and the quantity of the yttrium (Y) can be ascertained with an energy-dispersive X-ray spectroscopy (EDS) device. In another embodiment, the second phases 46 may be present on either of the insides and the surfaces of the aluminum nitride particles 44n.

The aluminum nitride particles 44n can be manufactured through a publicly-known process such as a carbothermal reduction and nitridation process or a direct nitridation process. In order to obtain spherical particles, the carbothermal reduction and nitridation process is preferable. This is because spherical alumina as a raw material for use in the carbothermal reduction and nitridation process is easily obtained. The aluminum nitride particles 44n can be manufactured through, for example, the following method.

A mixture of an aluminum nitride powder, a sintering additive powder, a binder, a dispersant, and a solvent is mixed, whereby a slurry is prepared. Then, the above slurry is dried through spray drying, whereby a granular compact is made. Here, the amount of yttrium oxide as the sintering additive powder is, for example, 2 to 6 parts by weight with respect to the aluminum nitride. After the spray drying, the granular compact is fired and pulverized, whereby aluminum nitride particles 44n (aluminum nitride powder) each having a surface and an inside on each of which second phases have been dispersed are obtained.

As described above, in the aluminum nitride particles 44n of the present embodiment, the second phases 46 containing yttrium have been deposited. In the course of integration between the AlN and Y₂O₃, decrease in lattice defects in the AlN and decrease in oxygen impurities in the AlN are realized. Meanwhile, lattice defects in the AlN and oxygen impurities in the AlN are not decreased by merely mixing the AlN powder and the Y₂O₃ powder. Thus, the thermal conductivity of the aluminum nitride particles 44n of the present embodiment can be improved as compared to aluminum nitride particles obtained by merely mixing the AlN powder and the Y₂O₃ powder.

The aluminum nitride particles of the present embodiment may have surfaces on which phosphorus (P) is present. The aluminum nitride particles manufactured as in the above manner is subjected to phosphoric acid treatment, whereby phosphorus can be contained on the surfaces of the aluminum nitride particles. In this case, the phosphorus on the surfaces of the aluminum nitride particles is present in the form of, for example, a phosphoric acid salt such as aluminum phosphate (AlPO₄). With such a configuration, the thermal resistance of the interface between each of the AlN particles and a resin (adhesive 42) such as silicone can be decreased, and the thermal conductivity of the adhesive layer 40 can be further increased. In addition, since phosphorus (P) is present on the surfaces of the aluminum nitride particles, the water resistance can be improved. As a result, the surfaces of the aluminum nitride particles can be inhibited from turning into alumina, and the thermal conductivity can be inhibited from decreasing.

As the adhesive included in the adhesive layer 40, for example, a silicone resin, an acrylic resin, an epoxy resin, or the like may be used. In particular, a silicone resin has comparatively excellent heat resistance and flexibility, and thus is desirable. A silicone resin has a comparatively low elastic modulus, and thus is highly capable of mitigating thermal stress generated in the adhesive layer 40.

As the adhesive included in the adhesive layer 40, for example, an adhesive composition (hereinafter, also referred to as “silicone resin composition”) containing a polyorganosiloxane (hereinafter, also referred to as “silicone resin”) may be used. The polyorganosiloxane contains R¹₃SiO_{1/2} units (hereinafter, also referred to as “M units”) at both respective terminals, m R²₂SiO_{2/2} units (hereinafter, also referred to as “first D units”), and n R³R⁴SiO_{2/2} units (hereinafter, also referred to as “second D units”), where m represents an integer of 1 or more, and n represents an integer of 1 or more. Such a polyorganosiloxane is represented by the following general formula (1).

(R¹₃SiO_{1/2})₂(R²₂SiO_{2/2})ₘ(R³R⁴SiO_{2/2})ₙ . . . general formula (1)
(R¹ and R² mutually independently represent unsubstituted or substituted aliphatic hydrocarbon groups each having 1 to 12 carbon atoms, R³ represents an unsubstituted or substituted aliphatic hydrocarbon group having 1 to 12 carbon atoms, or an unsubstituted or substituted aromatic hydrocarbon group having 6 to 10 carbon atoms, R⁴ represents an unsubstituted or substituted aromatic hydrocarbon group having 6 to 10 carbon atoms, and the above polyorganosiloxane includes, in one molecule thereof, at least two alkenyl groups directly bound to a silicon atom (Si atom).)

From the viewpoint of increasing the flexibility of the adhesive composition, it is preferable that neither an RSiO_{3/2} unit (T unit) nor an SiO_{4/2} unit (Q unit) is included in the polyorganosiloxane structure.

In the above general formula (1), each of R¹ and R² is more preferably an alkenyl group having 2 to 8 carbon atoms, or an unsubstituted or substituted monovalent hydrocarbon group having 1 to 12 carbon atoms and including no aliphatic unsaturated bond. Examples of the alkenyl group having 2 to 8 carbon atoms include a vinyl group, an allyl group, a propenyl group, an isopropenyl group, a butenyl group, a pentenyl group, a hexenyl group, a cyclohexenyl group, and the like. Examples of the unsubstituted or substituted monovalent hydrocarbon group having 1 to 12 carbon atoms and including no aliphatic unsaturated bond include: alkyl groups such as a methyl group, an ethyl group, a propyl group, an isopropyl group, a butyl group, an isobutyl group, a tert-butyl group, a pentyl group, a neopentyl group, a hexyl group, a heptyl group, an octyl group, a nonyl group, a decyl group, and a dodecyl group; cycloalkyl groups such as a cyclopentyl group, a cyclohexyl group, and a cycloheptyl group; aryl groups such as a phenyl group, a tolyl group, a xylyl group, a naphthyl group, and a biphenylyl group; aralkyl groups such as a benzyl group, a phenylethyl group, a phenylpropyl group, and a methylbenzyl group; groups each obtained by substituting at least one of the hydrogen atoms bound to the carbon atoms in any of these groups with a halogen atom such as fluorine, chlorine, or bromine, a cyano group, or the like; and the like.

At least one of “R¹”s contained in each of the M units in the above general formula (1) is more preferably an alkenyl group having 2 to 8 carbon atoms, further preferably a lower alkenyl group having 2 to 4 carbon atoms and exemplified by a vinyl group, an allyl group, a propenyl group, an isopropenyl group, and a butenyl group, and particularly preferably a vinyl group. The remaining two “R¹”s contained in the M unit in the above general formula (1) are mutually independently more preferably unsubstituted or substituted monovalent hydrocarbon groups each having 1 to 12 carbon atoms and each including no aliphatic unsaturated bond, further preferably lower alkyl groups each having 1 to 3 carbon atoms and each exemplified by a methyl group, an ethyl group, a propyl group, and an isopropyl group, and particularly preferably methyl groups. That is, it is preferable that: one of “R¹”s contained in the M unit in the above general formula (1) is a vinyl group; and the remaining two “R¹”s are methyl groups.

In the above general formula (1), R³ is more preferably an unsubstituted or substituted monovalent hydrocarbon group having 1 to 12 carbon atoms and including no aliphatic unsaturated bond, or an unsubstituted or substituted monovalent aromatic hydrocarbon group having 6 to 10 carbon atoms. The unsubstituted or substituted monovalent hydrocarbon group having 1 to 12 carbon atoms and including no aliphatic unsaturated bond can be exemplified by the same groups presented as examples of R¹ and R² in the above general formula (1). Examples of the unsubstituted or substituted monovalent aromatic hydrocarbon group having 6 to 10 carbon atoms include: aryl groups such as a phenyl group, a tolyl group, a xylyl group, and a naphthyl group; aralkyl groups such as a benzyl group, a 2-phenylethyl group, and a 2-phenylpropyl group; groups each obtained by substituting at least one of the hydrogen atoms bound to the carbon atoms in any of these groups with a halogen atom such as fluorine, chlorine, or bromine, a cyano group, or the like; and the like. In the above general formula (1), R³ is further preferably an aryl group exemplified by a phenyl group, a tolyl group, a xylyl group, and a naphthyl group and particularly preferably a phenyl group.

In the above general formula (1), R⁴ is more preferably an unsubstituted or substituted monovalent aromatic hydrocarbon group having 6 to 10 carbon atoms. The unsubstituted or substituted monovalent aromatic hydrocarbon group having 6 to 10 carbon atoms can be exemplified by the same groups presented as examples of R³ in the above general formula (1). In the above general formula (1), R⁴ is further preferably an aryl group exemplified by a phenyl group, a tolyl group, a xylyl group, and a naphthyl group and particularly preferably a phenyl group. In the above general formula (1), R³ and R⁴ are preferably the same substituent. The polyorganosiloxane represented by the above general formula (1) is particularly preferably a vinyl-terminated diphenylsiloxane-dimethylsiloxane copolymer.

The content of the above aromatic hydrocarbon groups in the above polyorganosiloxane is 3 mol % or higher and 16 mol % or lower. When the content of the above aromatic hydrocarbon groups in the above polyorganosiloxane is lower than 3 mol %, sufficient exhibition of an effect of decreasing a glass transition temperature by introducing the above aromatic hydrocarbon groups tends to become difficult. Meanwhile, when the content of the above aromatic hydrocarbon groups in the above polyorganosiloxane is higher than 16 mol %, an interaction between the above aromatic hydrocarbon groups tends to occur owing to π-π stacking, crystallization tends to occur, and the glass transition temperature tends to increase. The content of the above aromatic hydrocarbon groups in the above polyorganosiloxane is more preferably 4 mol % or higher and 14 mol % or lower and further preferably 5 mol % or higher and 12 mol % or lower.

The polyorganosiloxane contained in the above adhesive composition and having the above structure is preferably formed of a single type of polyorganosiloxane. The phrase “formed of a single type of polyorganosiloxane” means that all of polyorganosiloxanes composing the adhesive composition have a uniquely defined molecular structure in each of the substituents R¹, R², R³, and R⁴ in the above general formula (1). The phrase means that the above polyorganosiloxane is not a mixture of polyorganosiloxanes among which the molecular structures of all or any of the substituents R¹, R², R³, and R⁴ differ. An option of adding a silicone compound such as a silane coupling agent, a curing catalyst, or a crosslinking agent is not eliminated.

The above adhesive composition has a glass transition temperature (Tg) of −60 °C or lower. When the glass transition temperature of the adhesive composition is higher than −60 °C, properties related to flexibility, adhesiveness, and elongation tend to decrease in a low-temperature environment. In other words, properties that the adhesive layer 40 has as properties of a flexible elastomer or rubber tend to decrease. Meanwhile, when the glass transition temperature of the adhesive composition is −60 °C or lower, the properties related to flexibility, adhesiveness, and elongation tend to be maintained at favorable values even in a low-temperature environment. The glass transition temperature of the adhesive composition is more preferably −70 °C or lower and further preferably −80 °C or lower.

The amount of water in the above adhesive composition is 10 ppm or larger and 5000 ppm or smaller. The amount of water in the adhesive composition influences hydrolysis of a silane coupling agent contained in the adhesive composition. Here, the silane coupling agent exhibits an adhesion effect through hydrolysis. When said amount of water is smaller than 10 ppm, the amount is not sufficient for allowing hydrolysis of the silane coupling agent to favorably progress, and hence leads to hindrance to improvement of the adhesiveness of the adhesive layer 40. Meanwhile, when said amount of water is larger than 5000 ppm, the water contained in the adhesive layer 40 aggregates or dews on a joining surface for the plate-shaped portion 20 and a joining surface for the base portion 30 in the course of a heat cycle that involves heating and cooling during manufacturing of a semiconductor. The aggregation or dewing becomes a factor of decrease in the adhesiveness on each of these joining surfaces. The amount of water in the adhesive composition is more preferably 20 ppm or larger and 4000 ppm or smaller. Said amount of water can be measured with a Karl Fischer titrator.

The addition amount of the aluminum nitride particles 44n in the adhesive layer 40 is not particularly limited, but at least 30 wt % of the aluminum nitride particles 44n is preferably used in the adhesive 42. With such an addition amount, heat conduction of the adhesive layer 40 can be improved.

The adhesive layer 40 may further include: a catalyst for promoting a curing reaction; a silane coupling agent for promoting curing and adhesion, and imparting adhesiveness; a crosslinking agent; a reaction inhibitor for adjusting the curing speed of the adhesive; a viscosity adjusting agent; or the like.

The silane coupling agent may be added for the purpose of imparting adhesiveness. The silane coupling agent is not particularly limited, and any of conventional silane coupling agents that are publicly known may be used. As the silane coupling agent, it is possible to use, for example, vinyltrimethoxysilane, vinyltriethoxysilane, vinyltris (methoxyethoxy) silane, 2-(3,4-epoxycyclohexyl) ethyltrimethoxysilane, 3-glycidoxypropylmethyldimethoxysilane, 3-glycidoxypropyltrimethoxysilane, 3-glycidoxypropylmethyldiethoxysilane, 3-glycidoxypropyltriethoxysilane, p-styryltrimethoxysilane, 3-methacryloxypropylmethyldimethoxysilane, 3-methacryloxypropyltrimethoxysilane, 3-methacryloxypropyltriethoxysilane, 3-acryloxypropyltrimethoxysilane, 3-aminopropyltrimethoxysilane, 3-aminopropyltriethoxysilane, 3-mercaptopropyltrimethoxysilane, 3-isocyanatopropyltriethoxysilane, or the like. The above types of silane coupling agents may be used singly, or two or more of the above types of silane coupling agents may be used in combination. The addition amount of the silane coupling agent per 100 parts by weight of the above silicone resin is 0.1 parts by weight or larger and 20 parts by weight or smaller. When said addition amount is smaller than 0.1 parts by weight, a sufficient adhesiveness does not tend to be imparted to the above adhesive composition. Meanwhile, when said addition amount is larger than 20 parts by weight, curing of the polyorganosiloxane tends to be hindered. The said addition amount is more preferably 0.5 parts by weight or larger and 15 parts by weight or smaller and further preferably 1 part by weight or larger and 10 parts by weight or smaller. Instead of the above silane coupling agent, a titanate-based coupling agent or an aluminate-based coupling agent may be used.

The curing catalyst may be added for the purpose of promoting a curing reaction. The curing catalyst is not particularly limited, and any of conventional curing catalysts that are publicly known may be used. As the curing catalyst, it is possible to use, for example, organic tin, inorganic tin, a titanium catalyst, a bismuth catalyst, a metal complex, a platinum catalyst, a basic substance, an organic phosphorus oxide, or the like. The curing catalyst is more preferably a platinum catalyst or a rhodium catalyst. The platinum catalyst is, for example, chloroplatinic acid, alcohol-modified chloroplatinic acid, a platinum complex having a chelate structure, or the like. The above types of curing catalysts may be used singly, or two or more of the above types of curing catalysts may be used in combination. The addition amount of the curing catalyst with respect to the above polyorganosiloxane is 5 ppm or larger and 100 ppm or smaller on a platinum weight basis. When said addition amount is smaller than 5 ppm, curing of the above polyorganosiloxane does not tend to sufficiently progress. Meanwhile, when said addition amount is larger than 100 ppm, the curing progresses faster, and thus a uniform composition does not tend to be obtained. Said addition amount is more preferably 10 ppm or larger and 70 ppm or smaller and further preferably 15 ppm or larger and 40 ppm or smaller.

The crosslinking agent may be added for the purpose of reacting with an alkenyl-group-containing polyorganosiloxane so as to form a main backbone of the above polyorganosiloxane. The crosslinking agent is not particularly limited, and any of conventional crosslinking agents that are publicly known may be used. The crosslinking agent is preferably an organohydrogenpolysiloxane having at least three hydrosilyl groups in one molecule thereof. As such a crosslinking agent, it is possible to use, for example, polymethylhydrogensiloxane, poly (dimethylsiloxane-methylhydrogensiloxane), or the like. The above types of crosslinking agents may be used singly, or two or more of the above types of crosslinking agents may be used in combination. In a case where the addition amount of the crosslinking agent is expressed as “[Si—H]/[CH₂═CH—]” which is the molar ratio of an [Si—H] group in the crosslinking agent to a [CH₂=CH—] group in the alkenyl-group-containing polyorganosiloxane, the value of “[Si—H]/[CH₂═CH—]” is 0.5 or larger and 1.5 or smaller. When said addition amount is smaller than 0.5, the above polyorganosiloxane tends to be insufficiently crosslinked, and a sufficient strength does not tend to be obtained. Meanwhile, when said addition amount is larger than 1.5, the crosslinking tends to excessively progress, and thus the flexibility tends to be lost. Said addition amount is more preferably 0.7 or larger and 1.3 or smaller and further preferably 0.9 or larger and 1.1 or smaller.

The reaction inhibitor may be added for the purpose of adjusting the curing speed of the adhesive composition. The reaction inhibitor is not particularly limited, and any of conventional reaction inhibitors that are publicly known may be used. Examples of the reaction inhibitors include 3-methyl-1-butyn-3-ol, 3-methyl-1-pentyn-3-ol, 3,5-dimethyl-1-hexyn-3-ol, 1-ethynylcyclohexanol, 3-methyl-3-trimethylsiloxy-1-butyne, 3-methyl-3-trimethylsiloxy-1-pentyne, 3,5-dimethyl-3-trimethylsiloxy-1-hexyne, 1-ethynyl-1-trimethylsiloxycyclohexane, bis (2,2-dimethyl-3-butynoxy) dimethylsilane, 1,3,5,7-tetramethyl-1,3,5,7-tetravinylcyclotetrasiloxane, 1,3,5,7-tetramethyl-1,3,5,7-tetrahexenylcyclotetrasiloxane, 1,1,3,3-tetramethyl-1,3-divinyldisiloxane, triallyl isocyanurate, and the like. The reaction inhibitor is more preferably 1,3,5,7-tetramethyl-1,3,5,7-tetravinylcyclotetrasiloxane, 1,1,3,3-tetramethyl-1,3-divinyldisiloxane, or triallyl isocyanurate. The above types of reaction inhibitors may be used singly, or two or more of the above types of reaction inhibitors may be used in combination. The addition amount of the reaction inhibitor per 100 parts by weight of the above silicone resin is 10 parts by weight or smaller. When said addition amount is larger than 10 parts by weight, normal curing tends to be hindered, and imperfect curing tends to occur. The addition amount of the reaction inhibitor is more preferably 0.1 parts by weight or larger and 6 parts by weight or smaller and further preferably 0.2 parts by weight or larger and 2 parts by weight or smaller. The reaction inhibitor is optionally added as necessary in order to control the activity of the catalyst such as the platinum catalyst and prevent the adhesive composition from having an increased viscosity or from being formed into a gel before the adhesive composition is heated and cured.

The viscosity adjusting agent may be added for the purpose of adjusting the viscosity of the silicone resin in order to decrease a variation in the thickness of an adhesion sheet at the time of producing the sheet. The viscosity adjusting agent is not particularly limited, and any of conventional viscosity adjusting agents that are publicly known may be used. Examples of the viscosity adjusting agent include aerosol silica, fumed silica, colloidal silica, aerosol alumina, fumed alumina, colloidal alumina, and the like. The viscosity adjusting agent is more preferably aerosol silica or aerosol alumina. The above types of viscosity adjusting agents may be used singly, two or more of the above types of viscosity adjusting agents may be used in combination. The surface of the viscosity adjusting agent may be subjected to hydrophobization treatment (surface treatment) or the like. The addition amount of the viscosity adjusting agent per 100 parts by weight of the above silicone resin is 0.05 parts by weight or larger and 10 parts by weight or smaller. When said addition amount is smaller than 0.05 parts by weight, the viscosity adjustment effect does not tend to be obtained. Meanwhile, when said addition amount is larger than 10 parts by weight, the viscosity tends to excessively increase, the fluidity tends to decrease, and the variation in the thickness of the sheet tends to increase. The addition amount of the viscosity adjusting agent is more preferably 0.1 parts by weight or larger and 5 parts by weight or smaller and further preferably 0.5 parts by weight or larger and 2 parts by weight or smaller.

The adhesive layer 40 may contain, as a filler, another filler other than the above inorganic filler 44. As the other filler, it is possible to use, for example, silica (e.g., wet silica, dry silica, fumed silica, fused silica, fused spherical silica, or the like), alumina, boron nitride, zirconia, silicon nitride, silicon carbide, or the like. The other filler is more preferably silica, alumina, or boron nitride and further preferably alumina. For the adhesive layer 40, the above types of fillers may be used singly, or two or more of the above types of fillers may be used in combination in addition to the above inorganic filler 44.

The average particle diameter of the filler is not particularly limited but is preferably 5 nm or larger and 50 μm or smaller. When said average particle diameter is smaller than 5 nm, the specific surface area of the filler becomes large, whereby the surface of the filler is coated with a larger amount of the silicone resin than in a case where the specific surface area of the filler is small. Consequently, the amount of the silicone resin that can flow between the particles of the filler in the entirety of the adhesive composition tends to become small, and the viscosity of the resin tends to become high. Hence, the moldability at the time of sheet molding or the like tends to decrease. Meanwhile, when said average particle diameter is larger than 50 μm, the large particle diameter leads to the following tendency. That is, control of the thickness of the sheet at the time of sheet molding or the like becomes more difficult, and as a result, the flatness of the surface of the adhesive layer 40 becomes lower, than in a case where the particle diameter is small. The average particle diameter of the filler is more preferably 50 nm or larger and 40 μm or smaller and further preferably 100 nm or larger and 30 μm or smaller. The average particle diameter of the filler can be obtained as a mass-average value D50 (or median diameter) by performing particle size distribution measurement through a laser light diffraction method. The shape of the filler component is not particularly limited.

The surface of the filler may be subjected to hydrophobization treatment (surface treatment) from the viewpoint of improving dispersibility in the above polyorganosiloxane. For example, silica as the filler may be subjected to surface treatment with a surface treatment agent such as an organic silicon compound such as an organosilane, an organosilazane, or a diorganopolysiloxane. The addition amount of the surface treatment agent and the method for the surface treatment are not particularly limited.

The filler may be added to the adhesive composition in the form of powder or may be added to the adhesive composition in the form of slurry obtained by dispersing the filler in an organic solvent.

The addition amount of the filler per 100 parts by weight of the above silicone resin is 1 part by weight or larger and 600 parts by weight or smaller. When said addition amount is smaller than 1 part by weight, the effect of control of the thermal conductivity and the strength or the viscosity adjustment effect does not tend to be easily obtained. Meanwhile, when said addition amount is larger than 600 parts by weight, the flexibility of the adhesive composition tends to decrease. The addition amount of the filler is more preferably 100 parts by weight or larger and 500 parts by weight or smaller and further preferably 200 parts by weight or larger and 400 parts by weight or smaller.

The glass transition temperature of the adhesive layer 40 is not particularly limited but is preferably −100 °C or lower. Such a configuration can cause the adhesive layer to, even at −100 °C, be flexible and have stress relaxation properties, whereby stable joining and thermal conduction with no in-plane variation can be realized.

The adhesive layer 40 preferably has an elongation rate, at −60 °C, of 40% or higher. When the elongation rate, at −60 °C, of the adhesive layer 40 is lower than 40%, the elongation, at −60 °C, of the adhesive layer 40 itself tends to decrease. Meanwhile, when the elongation rate, at −60 °C, of the adhesive layer 40 is 40% or higher, the elongation of the adhesive layer 40 itself tends to be maintained at a favorable value even at −60 °C. The elongation rate, at −60 °C, of the adhesive layer 40 is more preferably 100% or higher and further preferably 200% or higher.

The adhesive layer 40 preferably has a shear strain, at −60 °C, of 100% or higher. When the shear strain, at −60 °C, of the adhesive layer 40 is lower than 100%, the adhesiveness between the adhesive layer 40 and each of the plate-shaped portion 20 and the base portion 30 tends to decrease at −60 °C Meanwhile, when the shear strain, at −60 °C, of the adhesive layer 40 is 100% or higher, the adhesiveness between the adhesive layer 40 and each of the plate-shaped portion 20 and the base portion 30 tends to be maintained at a favorable value even at −60 °C. The shear strain, at −60 °C, of the adhesive layer 40 is more preferably 200% or higher and further preferably 400% or higher. The shear strain is also referred to as a shear adhesion strain.

The adhesive layer 40 preferably has a storage elastic modulus, at −60 °C, of 30 MPa or lower. When the storage elastic modulus, at −60 °C, of the adhesive layer 40 is higher than 30 MPa, the flexibility of the adhesive layer 40 tends to decrease at −60 °C. Meanwhile, when the storage elastic modulus, at −60 °C, of the adhesive layer 40 is 30 MPa or lower, the flexibility of the adhesive layer 40 tends to be maintained at a favorable value even at −60 °C. The storage elastic modulus, at −60 °C, of the adhesive layer 40 is more preferably 20 MPa or lower and further preferably 5 MPa or lower. That is, the adhesive layer 40 preferably has: an elongation rate, at −60°C, of 40% or higher; a shear strain, at −60 °C, of 100% or higher; and a storage elastic modulus, at −60 °C, of 30 MPa or lower.

As described above, in the electrostatic chuck 10 according to the present embodiment, the inorganic filler 44 included in the adhesive layer 40 includes the aluminum nitride particles 44n in which the second phases 46 containing yttrium are present. Since the second phases containing yttrium are deposited in the aluminum nitride particles 44n, the amount of oxygen impurities in the aluminum nitride is decreased, whereby the thermal conductivity of the aluminum nitride particles as a filler can be improved.

There is a case where the adhesive layer 40 is in contact with water at the time of, for example: manufacturing the adhesive layer 40; performing ultrasonic flaw detection which is one of tests to be conducted on the electrostatic chuck 10; cleaning the electrostatic chuck 10; or using the electrostatic chuck 10. In this case, if no second phase containing yttrium is present in the aluminum nitride, the surface of the aluminum nitride might turn into alumina (Al₂O₃) owing to a reaction with the water. Meanwhile, in the electrostatic chuck 10 according to the present embodiment, the second phases containing yttrium are present in the aluminum nitride, lattice defects in the aluminum nitride are decreased, and the reactivity with water is decreased, whereby the surfaces of the aluminum nitride particles 44n can be inhibited from turning into alumina. Since alumina has a lower thermal conductivity than aluminum nitride, decrease of the thermal conductivity of the aluminum nitride particles can be inhibited by inhibiting the surfaces of the aluminum nitride particles from turning into alumina. As a result, thermal conduction through the adhesive layer 40 can be improved.

### EXAMPLES

Hereinafter, the holding device according to the present disclosure will be described by means of Examples. Here, sheet-shaped samples 1 to 11 were produced. The samples correspond to respective adhesive layers. Each of the adhesive layers contained: a silicone adhesive as an adhesive; and aluminum nitride particles as a filler. Among the adhesive layers, the addition amount of the filler, and presence/absence of a yttrium (Y) component in the aluminum nitride particles, varied.

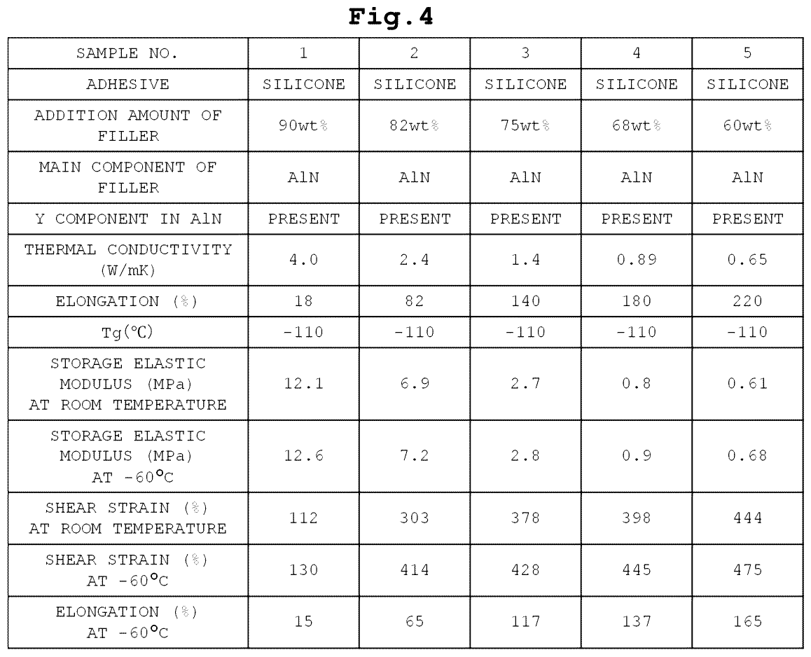

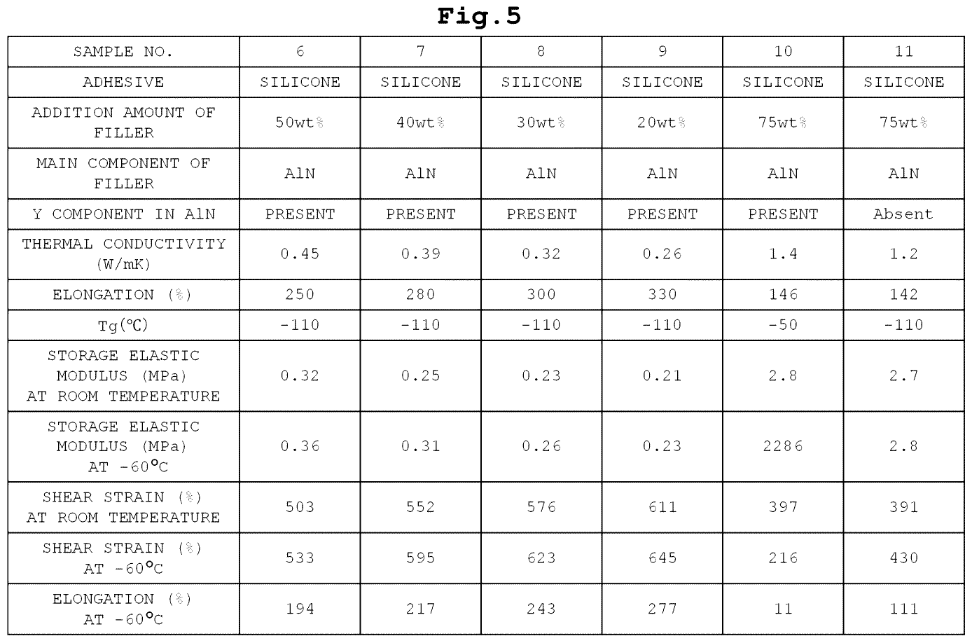

FIG. 4 and FIG. 5 show compositions, and evaluation results such as thermal conductivities and elongations, of the respective samples.

### Production of Each Sample

For each of the samples, a silicone resin was used as an adhesive. Specifically, one of polydimethylsiloxane and polydimethylsiloxane containing 5 mol % of phenyl group was used as a pre-curing adhesive material (resin material). Specifically, the polydimethylsiloxane containing 5 mol % of phenyl group was used for each of the samples 1 to 9 and the sample 11, and the polydimethylsiloxane was used for the sample 10. As shown in FIG. 4 and FIG. 5, the addition amount of the filler varied among the samples 1 to 9, the sample 10 (FIG. 5) differed from the sample 3 only in terms of the type of the adhesive, and the sample 11 (FIG. 5) differed from the sample 3 only in terms of the filler (in that the aluminum nitride particles contained no yttrium (Y)). The aluminum nitride particles in the samples 1 to 11 were not subjected to phosphoric acid treatment. The samples 1 to 10 correspond to Examples, and the sample 11 corresponds to a Comparative Example.

Each of the sheet-shaped samples was produced through the following method.

The corresponding filler (aluminum nitride particles) and the corresponding silicone resin were mixed to produce an adhesive in the form of paste. The method for the mixing is not particularly limited and may involve publicly-known mixing performed by using a stirring blade, three rolls, a kneader, a planetary centrifugal mixer, a planetary mixer, or the like. The produced adhesive in the form of paste was applied and spread on a film having mold releasability by using a publicly-known coating device and was cured, whereby a sheet-shaped sample was obtained. As the coating device, for example, a roll coater, a bar coater, a die coater, a knife coater, or the like may be used. As the film having mold releasability, for example, a polyethylene terephthalate (PET) film may be used, and a PET film on which a release agent has been applied in order to increase the mold releasability may be used. In order to obtain a thick cured product or a block-shaped cured product which are difficult to shape with the above various coating devices, the adhesive may be put into a container having a predetermined size, and then may be cured. Use of a container formed from polytetrafluoroethylene (PTFE) is suitable since the adhesive is easily taken out from such a container. Heating may be performed as necessary in order to achieve the curing. At the time of measuring thermal conductivity, the surface of the sample may be flattened by being polished in order to assuredly bring the surface into contact with a sensor.

### Evaluation Methods

### Thermal Conductivity

A thermal conductivity was measured by using a publicly-known thermal conductivity meter (C-Therm TCi), the measurement being performed on a disc-shaped sample having a diameter of about 40 mm and a thickness of about 10 mm. In the case of performing thermal conductivity measurement on a joining portion incorporated in an electrostatic chuck, the thermal conductivity may be measured after: grinding and removing a plate-shaped portion of the electrostatic chuck by using a surface grinding machine or the like so as to expose the joining portion; and then peeling the joining portion by using a knife or the like.

### Elongation

An elongation rate of each of the adhesive layers was measured through a tensile test (performed at 50 mm/min) by using a publicly-known tensile tester (e.g., AUTOGRAPH (AG-X plus 5 kN) manufactured by Shimadzu Corporation). Specifically, a test piece for the measurement was produced by: curing each of the adhesion sheets, which were produced as described above, at 100 °C for 10 hours; then further curing the adhesion sheet at 150 °C for 10 hours; and cutting the adhesion sheet into the shape of a strip having a width of 10 mm and a length of 70 mm. The thickness of the adhesion sheet was set to 0.35 mm. The test piece had portions extending by a length of 20 mm from both respective ends thereof. These portions were held with jigs, and the length of the intermediate portion, i.e., 30 mm, was regarded as a sample length. This test piece (adhesive composition) was pulled until the test piece was broken, and a difference obtained by subtracting an original sample length (in the above sample, the length of the intermediate portion, i.e., 30 mm) from a sample length (mm) at which the breakage occurred was divided by the original sample length (mm), whereby an elongation rate was calculated (see the following expression (1)).

Elongation (%)=[sample length (mm) at which breakage occurred−original sample length (mm)]/original sample length (mm)×100 (1)

Meanwhile, the elongation rate of an adhesive layer adhered on adherends can be measured through the following method. First, the adhesive layer is peeled from the adherends by using a knife or the like and is shaped so as to have, for example, a width of 10 mm and a length of 70 mm. In this state, the same measurement as that described above can be performed. Through the same measurement method as that described above, this test piece (adhesive layer) is pulled until the test piece is broken, and a difference obtained by subtracting the original sample length from the sample length (mm) at which the breakage has occurred is divided by the original sample length (mm), whereby an elongation rate can be calculated. For the measurement, the size and the shape of the test piece may be arbitrarily defined as long as the size and the shape allow the test piece to be held with jigs of a tensile tester. In addition, the thickness may also be arbitrarily defined, and thus the peeled adhesive composition can also be directly used for the measurement.

### Glass Transition Temperature

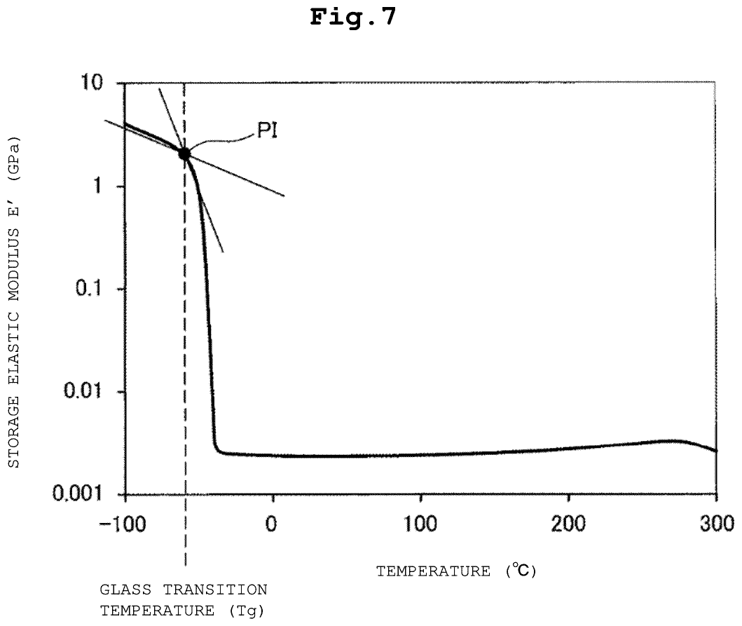

FIG. 7 is a graph showing a result of measuring the storage elastic modulus of an adhesive layer by using a dynamic viscoelasticity measuring device (DMA), with the vertical axis indicating storage elastic modulus E′ (GPa) and with the horizontal axis indicating temperature (°C). A glass transition temperature (Tg) was obtained as follows. That is, storage elastic moduli were measured by using the dynamic viscoelasticity measuring device (DMA), and the graph shown in FIG. 7 was obtained from the measurement results of the storage elastic moduli. In this graph, a temperature at a tangent intersection PI at which the storage elastic modulus of the adhesive layer started to significantly decrease was identified, and this temperature was regarded as a glass transition temperature (Tg). A test piece for the measurement was produced by: curing each of the adhesion sheets, which were produced as described above, at 100 °C for 10 hours; then further curing the adhesion sheet at 150 °C for 50 hours; and cutting the adhesion sheet into a width of 4 mm and a length of 50 mm.

### Storage Elastic Modulus

A storage elastic modulus of each of the adhesive layers was measured by using the dynamic viscoelasticity measuring device (DMA). The measurement was performed under conditions in which: a load was applied by means of tension; the preload was 1 g; the frequency was 11 Hz; the amplitude was 16 μm; and the temperature increase rate was 2 °C/min.

The measurement was performed while the temperature was being increased at the above temperature increase rate after the temperature was temporarily decreased from room temperature to −150 °C. Consequently, a storage elastic modulus at −60 °C was obtained. A test piece for the measurement was produced by: curing each of the adhesion sheets, which were produced as described above, at 100 °C for 10 hours; then further curing the adhesion sheet at 150 °C for 50 hours; and cutting the adhesion sheet into a width of 4 mm and a length of 50 mm. The test piece had an intermediate portion having a length of 40 mm, and the storage elastic modulus was measured at this portion.

Meanwhile, the storage elastic modulus of an adhesive layer adhered on adherends can be measured through the following method. First, the adhesive layer is peeled from the adherends by using a knife or the like and is cut so as to have, for example, a width of 4 mm and a length of 50 mm. In this state, the same measurement as that described above can be performed. The measurement is performed under conditions in which: a load is applied by means of tension; the preload is 1 g; the frequency is 11 Hz; the amplitude is 16 um; and the temperature increase rate is 2°C/min. The measurement is performed while the temperature is being increased at the above temperature increase rate after the temperature is temporarily decreased from room temperature to −150 °C. Consequently, a storage elastic modulus at −60 °C is obtained. The thickness may be arbitrarily defined, and thus the peeled adhesive layer can also be directly used for the measurement. Also, the glass transition temperature of the adhesive layer adhered on the adherends can be obtained through the following method. First, storage elastic moduli of the adhesive layer adhered on the adherends are measured, and a graph similar to the graph in FIG. 7 is obtained from the measurement results of the storage elastic moduli. In this graph, a temperature at the above tangent intersection PI is identified, and this temperature is regarded as a glass transition temperature (Tg).

### Shear Strain

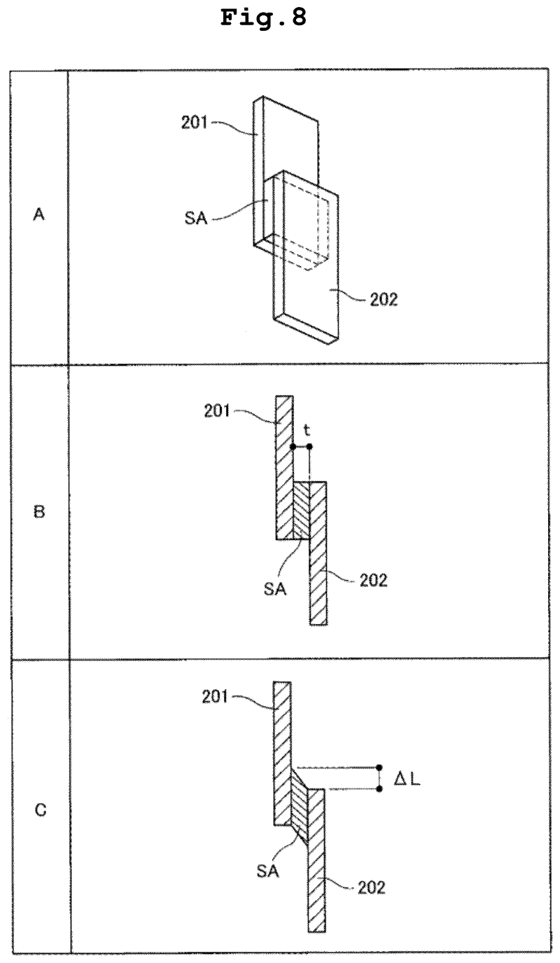

A shear strain of each of the adhesive layers was measured in a tensile test by using a publicly-known tensile tester (e.g., AUTOGRAPH (AG-X plus 5 kN) manufactured by Shimadzu Corporation). FIG. 8 is a diagram for schematically explaining a method for calculating the shear strain. First, a test piece for the measurement was produced. Specifically, two aluminum plates 201 and 202 each having a width of 12.5 mm, a length of 100 mm, and a thickness of 1 mm had end portions each measuring 12.5 by 12.5 mm, and adhesion sheets produced as described above were pasted on the respective end portions. Then, the two aluminum plates were pasted together in orientations allowing the aluminum plates to be pulled in mutually opposite directions. Then, the adhesion sheets were heated at 100 °C for 10 hours. Then, the adhesion sheets were further heated at 150 °C for 50 hours so as to achieve adhesion, thereby producing the test piece. Consequently, as shown in a field A and a field B in FIG. 8, the two adhesion sheets pasted on the two respective aluminum plates 201 and 202 were joined to each other, whereby an adhesive layer SA as a shear strain calculation target was formed. A total thickness t of thicknesses of the test pieces as the adhesive layers pasted on the two respective aluminum plates 201 and 202 was 0.7 mm. Next, the two aluminum plates 201 and 202 were moved relative to each other such that a shear force acted on the above adhesive layer SA. While one of the aluminum plates, i.e., aluminum plate 201, was being moved at a tension speed of 2 mm/min in one direction (e.g., the upward direction in a field C in FIG. 8) parallel to the adhesion surface, a load and a movement distance were measured by using a tensile tester, for example. The load was divided by the adhesion area (12.5 by 12.5 mm) of the adhesive composition having yet to be moved, whereby a shear adhesion stress was calculated. This relative movement between the two aluminum plates 201 and 202 was continued until the adhesive layer SA was broken. Then, a distance ΔL at which the shear adhesion stress was maximum was measured. Lastly, as in the following expression (4), the distance ΔL was divided by the total thickness t of the adhesive layer SA having yet to be moved, whereby a shear strain (%) of the adhesive layer SA was calculated.

Shear strain (%)=(ΔL/t)×100 (4)

Meanwhile, the shear strain of an adhesive layer adhered on adherends can be measured through the following method. First, the adhesive layer is cut together with the adherends through laser cutting or the like. The size and the shape of a test piece to be thus cut out only have to be a size and a shape that allow the test piece to be held with jigs of a tensile tester and that allow the two adherends adhered to each other by the adhesive layer to be pulled in mutually opposite directions as shown in FIG. 8. In addition, the thickness of the adhesive layer is also not particularly limited, and thus the adhesive layer having been cut out with the adherends being adhered thereto can also be directly used for the measurement. Before a tensile test is performed, the adhesion area of the adhesive layer on the cut-out test piece and the thickness of the adhesive layer are measured. Subsequently, a tension test is performed in the same method as that described above, and the distance ΔL at which the shear adhesion stress is maximum is divided by the total thickness t of the adhesive layer, whereby a shear strain (%) is calculated.

From the samples 1 to 9, it is found that a larger addition amount of the filler (aluminum nitride particles) resulted in a higher thermal conductivity of the adhesive layer, and meanwhile, resulted in lower elongations, lower shear strains, and higher storage elastic moduli. It is considered that a larger addition amount of the filler having a high thermal conductivity resulted in a higher thermal conductivity but resulted in a lower silicone resin content, and thus caused the adhesive to be harder and more easily breakable owing to deformation. In comparison between the measurement results at room temperature and the measurement results at −60 °C regarding the storage elastic moduli and the shear strains, both the storage elastic modulus and the shear strain in each of the samples 1 to 9 were slightly higher at −60 °C than at room temperature. This is considered to be because cooling resulted in, although the temperature was Tg or higher, slight hardening and increase in the adhesiveness. The addition amount of the aluminum nitride particles is preferably 20 wt % or higher and further preferably 30 wt % or higher. In consideration of achievement of both a favorable thermal conductivity and favorable elongations, the filler content is most preferably about 75 wt %, for example.

As described above, the sample 10 differed from the sample 3 in terms of the type of the adhesive. Since the sample 3 and the sample 10 had thermal conductivities equal to each other, it is found that the type of the adhesive does not influence the thermal conductivity. In addition, in the sample 10, since a polydimethylsiloxane containing no phenyl group was used, Tg was −50 °C, i.e., higher than Tg of the sample 3. As a result, the sample 10 had a storage elastic modulus at room temperature and a shear strain at room temperature which were approximately equal to those of the sample 3, but had: a storage elastic modulus, at −60 °C, of 2286 MPa which was much higher than the storage elastic modulus, at −60 °C, of the sample 3; a shear strain, at −60 °C, of 216% which was much lower than the shear strain, at −60 °C, of the sample 3; and an elongation, at −60 °C, of 11% which was much lower than the elongation, at −60 °C, of the sample 3. In this manner, all of these properties at −60 °C of the sample 10 significantly changed from those of the sample 3. Since −60 °C is lower than Tg of the sample 10, it is indicated that the properties of a flexible elastomer or rubber decreased.

As described above, the sample 11 differed from the sample 3 in that the filler was changed to a filler in which no second phase was present in the aluminum nitride particles. Since the sample 3 had a higher thermal conductivity than the sample 11, it is considered that the thermal conductivity can be improved by presence, in the aluminum nitride particles, of a second phase containing yttrium (Y). The results of the elongations, the storage elastic moduli, and the shear strains were approximately the same between the sample 3 and the sample 11. This is because the type and the content of the silicone resin were the same between the sample 3 and the sample 11.

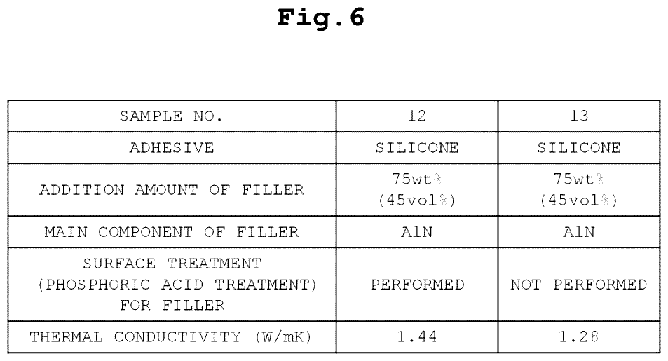

FIG. 6 is a diagram showing an advantageous effect exhibited by performing phosphoric acid treatment on aluminum nitride particles. Aluminum nitride particles in a sample 12 were subjected to phosphoric acid treatment, and aluminum nitride particles in a sample 13 were not subjected to phosphoric acid treatment. The other configurations were the same between the samples 12 and 13. Measurement for the Examples in FIG. 6 was performed separately from the measurement for the series of experiment examples in FIG. 4 and FIG. 5 in order to assuredly ascertain the advantageous effect of the phosphoric acid treatment. The sample 12 had a higher thermal conductivity than the sample 13. That is, presence of phosphorus on the surfaces of the aluminum nitride particles enable further improvement of the thermal conductivity. The samples 12 and 13 each correspond to an Example.

In the adhesive layer 40, heat is transmitted owing to molecular vibration of the adhesive (silicone resin) and lattice vibration of the inorganic filler. In the adhesive layer 40 which is a complex of the silicone resin and the inorganic filler, the thermal conductivity can be increased by allowing vibration therebetween to be efficiently transmitted. In comparison between the thermal conductivity obtained in the case of using a filler that was not subjected to surface treatment (phosphoric acid treatment) (sample 13) and the thermal conductivity obtained in the case of using a filler that was subjected to surface treatment so as to distribute phosphorus on the surface of the filler (sample 12), the thermal conductivity was higher in the case of performing surface treatment.

AlN fillers have comparatively high polarities, and meanwhile, silicone resins have comparatively low polarities. Thus, it is inferred that the AlN filler that was not subjected to surface treatment and the silicone resin each had a low wettability, and transmission of lattice vibration was hindered, so that the thermal conductivity became low. Meanwhile, it is inferred that the AlN filler that was subjected to surface treatment so as to distribute phosphorus on the surface thereof had an enhanced wettability, had an increased transmission efficiency for lattice vibration, and had a layer of the phosphorus formed thereon, so that the thermal conductivity of the adhesive became high.

The present disclosure is not limited to the above embodiments or the like and may be implemented in various configurations without departing from the gist of the present disclosure. For example, the technical features in the embodiments corresponding to the technical features in the respective aspects described in the section “SUMMARY OF THE INVENTION” may be replaced or combined as appropriate to solve some or all of the above problems or to achieve some or all of the above advantageous effects. Also, a technical feature may be deleted as appropriate unless the technical feature is described as an indispensable feature in the present description.

The present disclosure can be implemented as in the following application examples as well.

### Application Example 1

A holding device configured to hold a target object, the holding device comprising:
a plate-shaped portion formed in a plate shape;
a base portion supporting the plate-shaped portion and formed in a plate shape; and
an adhesive layer disposed between the plate-shaped portion and the base portion and including an adhesive and an inorganic filler, the adhesive layer joining the plate-shaped portion and the base portion, wherein
the inorganic filler includes an aluminum nitride particle in which a second phase containing yttrium is present.

### Application Example 2

The holding device in accordance with application example 1, wherein
the aluminum nitride particle has a surface on which phosphorus is present.

### Application Example 3

The holding device in accordance with application example 1 or 2, wherein
the adhesive layer has a glass transition temperature of −100 °C or lower.

### Application Example 4

The holding device in accordance with any one of application examples 1 to 3, wherein
the adhesive layer has
an elongation rate, at −60 °C, of 40% or higher,
a shear strain, at −60 °C, of 100% or higher, and
a storage elastic modulus, at −60 °C, of 30 MPa or lower.

### DESCRIPTION OF REFERENCE NUMERALS

10: electrostatic chuck
20: plate-shaped portion
22: attraction electrode
24: first surface
26: second surface
30: base portion
32: coolant flow path
40, SA: adhesive layer
42: adhesive
44: inorganic filler
44n: aluminum nitride particle
46: second phase
46f: on-surface second phase
46i: on-inside second phase
50: gas supply path
52: gas discharge port
W: wafer
201, 202: aluminum plate

1. A holding device configured to hold a target object, the holding device comprising:
a plate-shaped portion formed in a plate shape;
a base portion supporting the plate-shaped portion and formed in a plate shape; and
an adhesive layer disposed between the plate-shaped portion and the base portion and including an adhesive and an inorganic filler, the adhesive layer joining the plate-shaped portion and the base portion, wherein
the inorganic filler includes an aluminum nitride particle in which a second phase containing yttrium is present.

2. The holding device in accordance with claim 1, wherein
the aluminum nitride particle has a surface on which phosphorus is present.

3. The holding device in accordance with claim 1, wherein
the adhesive layer has a glass transition temperature of −100 °C or lower.

4. The holding device in accordance with claim 1, wherein
the adhesive layer has
an elongation rate, at −60 °C, of 40% or higher,
a shear strain, at −60 °C, of 100% or higher, and
a storage elastic modulus, at −60 °C, of 30 MPa or lower.

5. The holding device in accordance with claim 2, wherein
the adhesive layer has
an elongation rate, at −60 °C, of 40% or higher,
a shear strain, at −60 °C, of 100% or higher, and
a storage elastic modulus, at −60 °C, of 30 MPa or lower.

6. The holding device in accordance with claim 3, wherein
the adhesive layer has
an elongation rate, at −60 °C, of 40% or higher,
a shear strain, at −60 °C, of 100% or higher, and
a storage elastic modulus, at −60 °C, of 30 MPa or lower.
